(19) United States
(12) Patent Application Publication
(10) Pub. No.: US 2023/0420606 A1
(43) Pub. Date: Dec. 28, 2023

(54) METHOD FOR MANUFACTURING TERAHERTZ DEVICE

(71) Applicant: National Tsing Hua University, Hsinchu City (TW)

(72) Inventors: Shang-Hua Yang, Hsinchu City (TW); Wang-Chien Chen, Hsinchu City (TW); Tsung-Han Wu, Hsinchu City (TW)

(73) Assignee: National Tsing Hua University, Hsinchu City (TW)

(21) Appl. No.: 17/892,099

(22) Filed: Aug. 21, 2022

(30) Foreign Application Priority Data
Jun. 28, 2022 (TW) 111123986

(51) Int. Cl. H01L 33/00; H01L 33/32

(52) U.S. Cl. CPC H01L 33/0095; H01L 33/32

(57) ABSTRACT

The present disclosure provides a method for manufacturing a terahertz (THz) device. The method includes a step of forming a light-absorbing structure on a substrate by using a chemical vapor deposition (CVD) process. The substrate includes a semiconductor structure, a sapphire substrate, a quartz substrate, or a combination thereof. The light-absorbing structure includes a semiconductor material, a two-dimensional material, a low-dimensional material, a magnetic material, a topological material, or a combination thereof.

### CROSS-REFERENCE TO RELATED APPLICATION

This application claims the priority benefit of Taiwan application serial no. 111123986, filed on Jun. 28, 2022. The entirety of the above-mentioned patent application is hereby incorporated by reference herein and made a part of this specification.

### BACKGROUND OF THE INVENTION

### 1. Field of the Invention

The present invention relates to a method for manufacturing a light-absorbing structure, and particularly relates to a method for manufacturing a terahertz (THz) device.

### 2. Description of Related Art

THz has conducted to a great variety of unique applications such as high-speed communication, non-destructive imaging, chemical identification, material characterization, and biomedical sensing. Among various THz emitting and sensing technologies, photoconductive THz devices are widely adopted in THz systems due to their compact size, room temperature operation, and broad bandwidth. Materials for the conventional photoconductive THz devices are mainly based on low-temperature-grown (LT) materials such as LT-GaAs or LT-InGaAs. In general, the LT materials are grown through a molecular beam epitaxy (MBE) process under an ultra-high vacuum environment, such that precise controls for the epitaxial conditions of the MBE process are required to obtain a high-quality structure. As a result, a complex fabrication process and time-consuming nature lead to high manufacturing costs, and thus obstructs THz devices from being mass-produced and fully commercialized.

### SUMMARY OF THE INVENTION

The present invention provides a method for manufacturing a terahertz (THz) device in which a light-absorbing structure of the THz device is designed to be formed by a chemical vapor deposition (CVD) process, so that the THz device has lower manufacturing costs and production time as compared to the THz device formed by a molecular beam epitaxy (MBE) process and thus is benefit to the mass production and full commercialization. Moreover, the THz device formed by the CVD process has comparable performances (e.g., power or bandwidth performance) as compared to the THz device formed by the MBE process.

An embodiment of the present invention provides a method for manufacturing a THz device, which includes a step of forming a light-absorbing structure on a substrate by using a CVD process. The substrate includes a semiconductor substrate, a sapphire substrate, a quartz substrate, or a combination thereof. The light-absorbing structure includes a semiconductor material, a two-dimensional material, a low-dimensional material, a magnetic material, a topological material, or a combination thereof.

In some embodiments, the CVD process is performed at a pressure ranging from about 10 torr to about 100 torr.

In some embodiments, the substrate is a semiconductor substrate including GaAs, InP, SiC, sapphire, silica, GaN, or Si, and the light-absorbing structure is a semiconductor structure including a III-V compound, a IV element, a IV compound, or a combination thereof.

In some embodiments, the substrate is a semiconductor substrate including GaAs, and the semiconductor structure is a single-laver semiconductor including InGaAs.

In some embodiments, a gas source used in the CVD process includes AsH₃, a trimethyl (TMGa), and a trimethyl indium (TMIn).

In some embodiments, the substrate is a semiconductor substrate comprises InP, and the semiconductor structure is a stacked layer including at least one first semiconductor layer and at least one second semiconductor layer. The first semiconductor layer includes InAlAs, and the second semiconductor layer includes InGaAs.

In some embodiments, the at least one first semiconductor layer includes a plurality of first semiconductor layers, and the at least one second semiconductor layer includes second semiconductor layers. The plurality of first semiconductor layers and the plurality of second semiconductor layers are alternately stacked with each other.

In some embodiments, the substrate is a semiconductor substrate including Si, and the semiconductor structure is a stacked layer including a first semiconductor layer and a second semiconductor layer or a single-layer semiconductor including Ge, GeSn, or GaAs. The first semiconductor layer includes Ge, and the second semiconductor layer includes GeSn.

In some embodiments, the first semiconductor layer is formed on the substrate by using a first CVD process, and the second semiconductor layer is formed on the first semiconductor layer by using a second. CVD process. A gas source used in the first CVD process includes H₂ and GeH₄, and a gas source used in the second CVD process includes Ge₄H₆ and SnCl₄.

In some embodiments, the temperature used in the first CVD process is about 375° C. to about 400° C., and the temperature used in the second CVD process is about 320° C.

Based on the above, in the method for manufacturing the THz device, the light-absorbing structure of the THz device is designed to be formed by the CVD process, so that the THz device has lower manufacturing costs, lower production time, and higher yield as compared to the THz device formed by the MBE process, and thus is benefit to the mass production and full commercialization. Moreover, the THz device formed by the CVD process has comparable performances (e.g., power or bandwidth performance) as compared to the THz device formed by the MBE process.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view of a terahertz (THz) device according to the first embodiment of the present invention.

FIGS. 2A and 2B are diagrams showing the performance comparison between a THz device formed by a chemical vapor deposition (CVD) process according to an embodiment of the present invention and a THz device formed by a MBE growth process.

FIGS. 3A and 3B are diagrams showing the performance of a THz device formed by a CVD process according to another embodiment of the present invention.

FIG. 4 is a schematic cross-sectional view of a THz device according to the second embodiment of the present invention.

FIG. 5 is a schematic cross-sectional view of a THz device according to the third embodiment of the present invention.

FIG. 6 is a schematic cross-sectional view of a THz device according to the fourth embodiment of the present invention.

FIGS. 7A and 7B are diagrams showing the performance of a THz device formed by a CVD process according to yet another embodiment of the present invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements.

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Further ore, the “about”, “approximate” or “substantially” used herein may be based on the optical property, etching property or other properties to select a more acceptable deviation range or standard deviation, but may not apply one standard deviation to all properties. The terms used herein are used to merely describe exemplary embodiments and are not used to limit the present disclosure. In this case, unless indicated in the context specifically otherwise the singular forms include the plural forms.

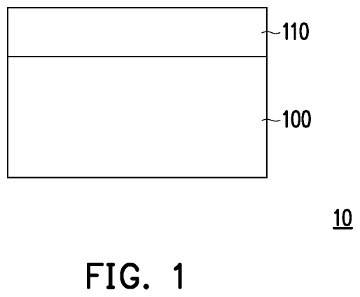

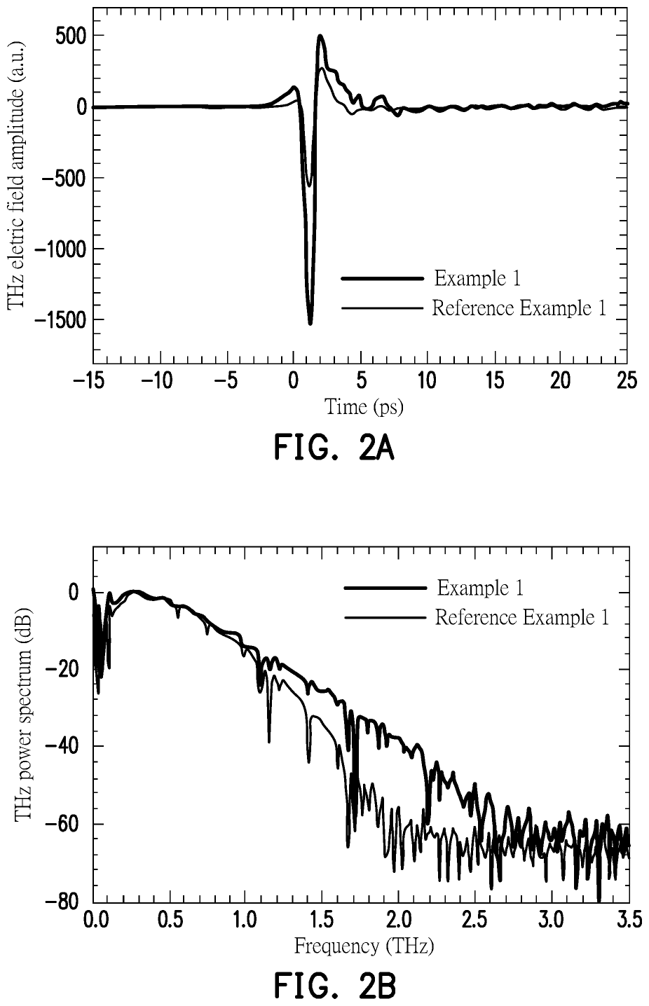

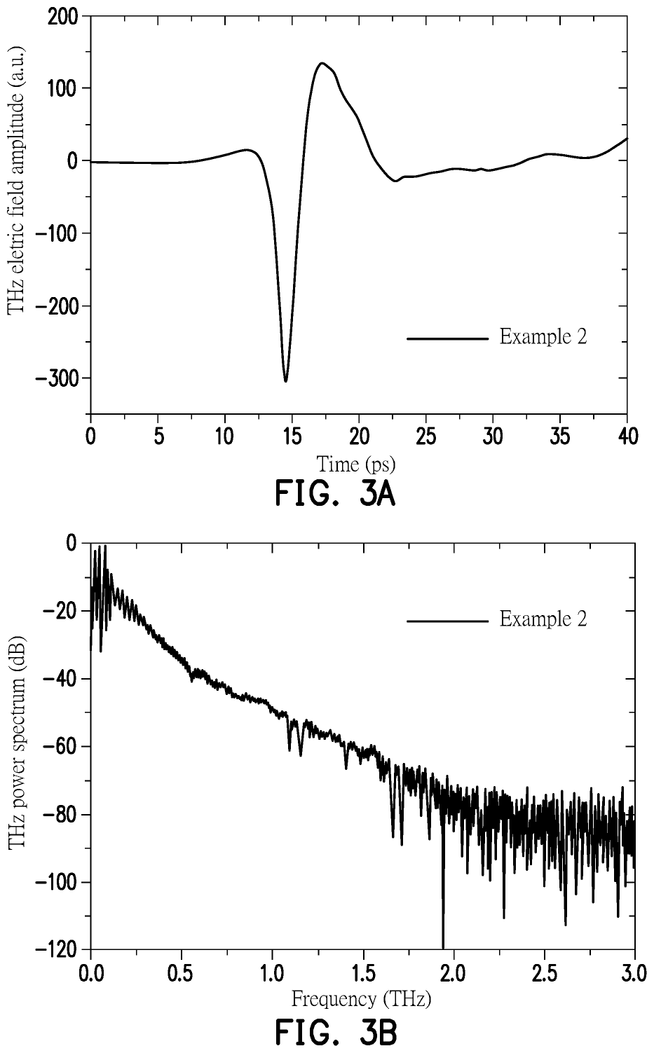

FIG. 1 is a schematic cross-sectional view of a terahertz (THz) device according to the first embodiment of the present invention. FIGS. 2A and 2B are diagrams showing the performance comparison between a THz device formed by a CVD process according to an embodiment of the present invention and a THz device formed by a MBE growth process. FIGS. 3A and 3B are diagrams showing the performance of a THz device formed by a CVD process according to another embodiment of the present invention.

Referring to FIG. 1, a light-absorbing structure 110 is formed on a substrate 100 by using a chemical vapor deposition (CVD) process. The substrate 100 includes a semiconductor substrate, a sapphire substrate, a quartz substrate, or a combination thereof. In some embodiments, the substrate 100 may be a semiconductor substrate including GaAs, InP, SiC, sapphire, silica, GaN, or Si. The light-absorbing structure 110 includes a semiconductor material, a two-dimensional material, a low-dimensional material, a magnetic material, a topological material, or a combination thereof In some embodiments, the light-absorbing structure 110 may be a semiconductor structure including a III-V compound, a IV element, a IV compound, or a combination thereof. The III-V compound may include, for example, InGaAs or InAlAs. The IV element may include, for example, Ge. The IV compound may include, for example, GeSn. The two-dimensional material may include, for example, binary compounds such as MoS₂, BN, MoSe₂, WSe₂. The magnetic material may include, for example, elements such as Co, binary compounds such as CoPt₃, ternary compounds such as CoFeB, other multinary compounds, or combinations thereof. The topological material may include, for example, a binary compound, a ternary compound, or a multinary compound. For example, the topological material may include the binary compound such as Bi₂Te₃ or Sb₂Te₃, or the ternary compound, such as (Bi_{0.57}Se_{0.43})₂Te₃.

In some embodiments, the light-absorbing structure 110 may be formed by depositing a semiconductor material through the CVD process at a pressure ranging from about 10 torr to about 100 torr. As such, the required equipment and time to achieve an ultra-high vacuum environment can be omitted as compared to the MBE growth process being performed in the ultra-high vacuum environment (e.g., 10⁻⁹ torr), and thus the manufacturing costs and production time for the THz device 10 can be decreased significantly and the yield for the THz device 10 can be increased. In some embodiments, in the case where the light-absorbing structure 110 is a semiconductor structure, the THz device 10 formed by the above CVD process have a resistivity ranging from about 10k ohm/sq to about 100M ohm/sq, a carrier mobility ranging from about 100 cm²/V−s to about 2000 cm²/V−s, and a carder lifetime ranging from about 1 ps to about 500 ps. Based on the above, the THz device formed by the CVD process has lower manufacturing costs, lower production time and higher yield as compared to the THz device formed by the MBE process and thus is benefit to the mass production and full commercialization. Moreover, the THz device formed by the CVD process has comparable performances (e.g., power or bandwidth performance) as compared to the device formed by the MBE process. In some embodiments, the CVD process is performed by controlling the temperature of the substrate at about 400° C. to about 800° C.

In some embodiments, the above CVD process may include a metal-organic CVD (MOCVD), a plasma-enhanced CVD (PECVD), a remote plasma-enhanced CVD (RPECVD), a reduced-pressure CVD (RPCVD), an atmospheric pressure CVD (APCVD), a low-pressure CVD (LPCVD), an aerosol assisted CVD (AACVD), a direct liquid injection CVD (DLICVD), a microwave plasma-assisted CVD (MPCVD), an atomic layer CVD (ALCVD), a hot wire CVD (HWCVD), a hot filament CVD (HFCVD), a hybrid physical-chemical vapor deposition (HPCVD), a rapid thermal CVD (RTCVD), or a combination thereof.

In some embodiments, the substrate 100 is a semiconductor substrate including GaAs, InP, or Si, and the light-absorbing structure 110 is a semiconductor structure including a III-V compound, a IV element, a IV compound, or a combination thereof. In some embodiments, the substrate is a semiconductor substrate including GaAs, and the semiconductor structure is a single-layer semiconductor including InGaAs. In some embodiments, in the case where the semiconductor structure is the single-layer semiconductor including InGaAs, a gas source used in the CVD process includes AsH₃, trimethyl gallium (TMGa), and trimethyl indium (TMIn). In some embodiments, the molar ratio of In, Ga and As in InGaAs may be 0.2:0.8:1 (which may be expressed as In_{0.2}Ga_{0.8}As).

In some embodiments, dopants may be doped in the semiconductor structure through a doping process to further increase the resistivity of the semiconductor material and obtain a shorter lifetime carrier cycle, which is benefit to improve the power and bandwidth performance of the THz device. For example, elements such as Be, C, Au, Rh, Er, or Fe may be doped in the semiconductor structure. In some embodiments, in the case where the light-absorbing structure 110 is a semiconductor structure including the III-V compound such as InGaAs or InAlAs, the elements such as Be can be doped in the semiconductor structure.

Referring to a result shown in FIGS. 2A and 2B. Example 1 is a THz device (e.g., THz device 10) formed by a CVD process. The CM process was conducted, for example, in a condition where the temperature was about 700° C. and the pressure was about 40 torr Reference Example 1 is a THz device formed by the MBE growth process. From the result shown in FIGS. 2A and 2B, the THz device 10 has superior signal strength (e.g., 20 dB or more) at high frequency (e.g., 1.0 THz to 2.5 THz) under femtosecond laser excitation with a central wavelength of 780 nm.

Moreover, as compared to the THz device formed by the MBE growth process, the manufacturing costs and production time for the THz device 10 can be decreased significantly and the yield for the THz device 10 can be increased. For example, the CVD process is performed at a pressure raging from about 10 torr to about 100 ton, which can omit the required equipment and time to achieve an ultra-high vacuum environment as compared to the MBE growth process being performed in the ultra-high vacuum environment 10⁻⁹ torr). In some alternative embodiments, the CVD process is performed at a pressure raging from about 37 torr to about 75 torr.

Referring to a result shown in FIGS. 3A and 3B, Example 2 is a THz device formed by a CVD process. The CVD process was conducted, for example, in a condition where the temperature was about 700° C. and the pressure was about 40 torr. The difference between the Examples 1 and 2 lies in that the THz device of the Example 1 further includes a nano structure being capable of improving the quantum efficiency. From the result shown in FIGS. 3A and 3B, the THz device of the Example 2 (without nano structure) has a bandwidth exceeding 2 THz and a signal-to-noise ratio (SNR) more than 50 dB under the excitation of a femtosecond laser with a central wavelength of 780 nm.

In some embodiments, in the case where the substrate 100 is a semiconductor substrate including GaAs and the light-absorbing structure 110 is a semiconductor structure including a single-layer semiconductor including InGaAs, the central wavelength range of the femtosecond laser used for the THz device 10 is about 500 nm to about 1600 nm. In some embodiments, the thickness of the single-layer semiconductor is about 10 μm to about 2 μm.

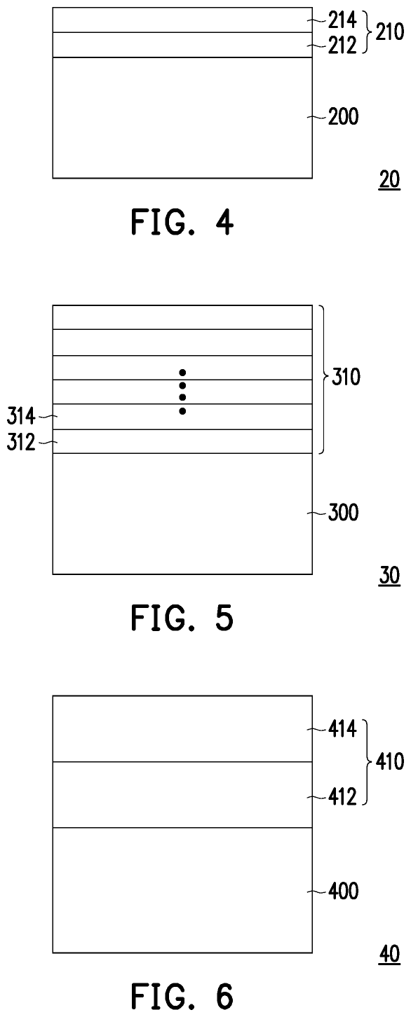

FIG. 4 is a schematic cross-sectional view of a THz device according to the second embodiment of the present invention.

Referring to FIG. 4, a method for manufacturing a THz device 20 includes a step of forming a light-absorbing structure 210 on a substrate 200 by using a CVD process. The light-absorbing structure 210 may be a semiconductor structure being a stacked layer including at least one first semiconductor layer 212 and at least one second semiconductor layer 214. In some embodiments, the substrate 200 may be a semiconductor substrate including InP, the first semiconductor layer 212 may include InAlAs, and the second semiconductor layer 214 may include InGaAs.

FIG. 5 is a schematic cross-sectional view of a THz device according to the third embodiment of the present invention.

Referring to FIG. 5, a method for manufacturing a THz device 30 includes a step of forming a light-absorbing structure 310 on a substrate 300 by using a CVD process. The light-absorbing structure 310 may be a semiconductor structure being a stacked layer including a plurality of first semiconductor layer 312 and a plurality of second semiconductor layer 314, and the plurality of first semiconductor layer 312 and the plurality of second semiconductor layer 314 may be alternately stacked with each other. In some embodiments, in the case where the substrate 300 is a semiconductor substrate including InP, the first semiconductor layer 312 includes InAlAs, and the second semiconductor layer 314 includes InGaAs, the central wavelength range of the femtosecond laser used for the THz device 30 is about 500 nm to about 1600 nm.

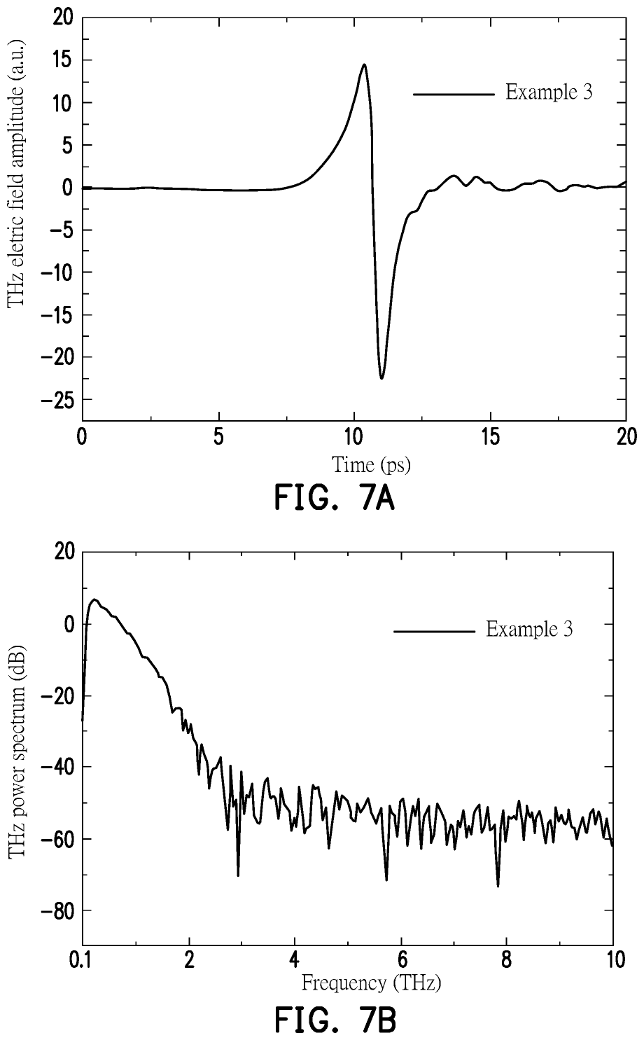

FIG. 6 is a schematic cross-sectional view of a THz device according to the fourth embodiment of the present invention. FIGS. 7A and 7B are diagrams showing the performance of a THz device formed by a CVD process according to yet another embodiment of the present invention.

Referring to FIG. 6, a method for manufacturing a THz device 40 includes a step of forming a light-absorbing structure 410 on a substrate 400 by using a CVD process. The light-absorbing structure 410 may be a semiconductor structure being a stacked layer including a first semiconductor layer 412 and a second semiconductor layer 414. In some embodiments, the light-absorbing structure 410 may be formed by depositing a semiconductor material through the CVD process at a pressure ranging from about 10 torr to about 100 torr. As such, the required equipment and time to achieve an ultra-high vacuum environment can be omitted as compared to the MBE growth process being performed in the ultra-high vacuum environment (e.g., 10⁻⁹ torr), and thus the manufacturing costs and production time for the THz device 40 can be decreased significantly and the yield for the THz device 40 can be increased. In some alternative embodiments, the CVD process is performed at a pressure raging from about 37 torr to about 75 torr.

In some embodiments, in the case where the substrate 400 is a semiconductor substrate including Si, the first semiconductor layer 412 includes Ge, and the second semiconductor layer 414 includes GeSn, the THz device 40 has a bandwidth exceeding 2 THz and a SNR more than 50 dB under the excitation of a femtosecond laser with a central wavelength of 1560 nm (e.g., Example 3 shown in FIGS. 7A and 7B). In addition, the THz device 40 formed by the above CVD process have a resistivity of about 22k ohm/sq, a carrier mobility ranging from about 500 cm²/V−s to about 2000 cm²/V−s, and a carrier lifetime of about 464 ps. Based on the above, the THz device formed by the CVD process has lower manufacturing costs, lower production time, and higher yield as compared to the THz device formed by the MBE process and thus is benefit to the mass production and full commercialization. Moreover, the THz device formed by the CVD process has comparable performances (e.g., power or bandwidth performances as compared to the THz device formed by the MBE process.

The first semiconductor layer 412 may be formed on the substrate 400 by using a first CVD process, and the second semiconductor layer 414 may be formed on the first semiconductor layer 412 by using a second CVD process. In some embodiments, in the case where the first semiconductor layer 412 includes Ge and the second semiconductor layer 414 includes GeSn, a gas source used in the first CVD process includes H₂ and GeH₄, and a gas source used in the second CVD process includes Ge₂H₆ and SnCl₄. In some embodiments, in the case where the second semiconductor layer 414 is formed by the above second CVD process, the molar ratio of Ge and Sn in GeSn may be 0.96:0.04 (which may be expressed as Ge_{0.96}Sn_{0.04}). In some embodiments, the first CVD process is performed by controlling the temperature of the substrate at about 375° C. to about 400° C. In some embodiments, the second CVD process is performed by controlling the temperature of the substrate at about 320° C. The thickness of the first semiconductor layer 412 and/or the second semiconductor layer 414 is about 10 nm to about 2 μm. For example, the thickness of the first semiconductor layer 412 is about 120 nm, and the thickness of the second semiconductor layer 414 is about 150 nm.

Based on the above, in the method for manufacturing the THz device, the light-absorbing structure of the THz device is designed to be formed by the CVD process, so that the THz device has lower manufacturing costs, lower production time, and higher yield as compared to the THz device formed by the MBE process and thus is benefit to the mass production and full commercialization. Moreover, the performance such as power or bandwidth performance of the THz device formed by the CVD process are comparable to that of the THz device formed by the MBE process.

It will be apparent to those skilled in the art that various modifications and variations can be made to the disclosed embodiments. It is intended that the specification and examples be considered as exemplary only, with a true scope of the disclosure being indicated by the following claims and their equivalents

What is clamed is:

1. A method for manufacturing a terahertz (THz) device, comprising:
forming a light-absorbing structure on a substrate by using a chemical vapor deposition (CVD) process, wherein:
the substrate comprises a semiconductor substrate, sapphire substrate, a quartz substrate, or a combination thereof; and
the light-absorbing structure comprises a semiconductor material, a two-dimensional material, a low-dimensional material, a magnetic material, a topological material, or a combination thereof.

2. The method of claim 1, wherein the CVD process is performed at a pressure ranging from about 10 torr to about 100 torr.

3. The method of claim 1, wherein the substrate is a semiconductor substrate comprising GaAs, InP, or Si, and the light-absorbing structure is a semiconductor structure comprising a III-V compound, a IV element, a IV compound, or a combination thereof.

4. The method of claim 3, wherein the substrate is a semiconductor substrate comprising GaAs, and the semiconductor structure is a single-layer semiconductor comprising InGaAs.

5. The method of claim 4, wherein a gas source used in the CVD process comprises AsH₃, trimethyl gallium (TMGa), and trimethyl indium (TMIn).

6. The method of claim 3, wherein the substrate is a semiconductor substrate comprises InP, the semiconductor structure is a stacked layer comprising at least one first semiconductor layer and at least one second semiconductor layer, the first semiconductor layer comprises InAlAs, and the second semiconductor layer comprises InGaAs.

7. The method of claim 6, wherein the at least one first semiconductor layer comprises a plurality of first semiconductor layers, the at least one second semiconductor layer comprises second semiconductor layers, and the plurality of first semiconductor layers and the plurality of second semiconductor layers are alternately stacked with each other.

8. The method of claim 3, wherein the substrate is a semiconductor substrate comprising Si, the semiconductor structure is a stacked layer comprising a first semiconductor layer and a second semiconductor layer or a single-layer semiconductor comprising Ge, GeSn, or GaAs, the first semiconductor layer comprises Ge, and the second semiconductor layer comprises GeSn.

9. The method of claim 8, wherein the first semiconductor layer is formed on the substrate by using a first CVD process, the second semiconductor layer is formed on the first semiconductor layer by using a second CVD process, a gas source used in the first CVD process comprises H₂ and GeH₄, and a gas source used in the second CVD process comprises Ge₂H₆ and SnCl₄.

10. The method of claim 9, wherein a temperature used in the first CVD process is about 375° C. to about 400° C. and a temperature used in the second CVD process is about 320° C.
